(19) United States
(12) Patent Application Publication
(10) Pub. No.: US 2001/0040975 A1
(43) Pub. Date: Nov. 15, 2001

(54) DEVICE INCLUDING A BUILT-IN ELECTROACOUSTIC TRANSDUCER FOR OPTIMUM SPEECH REPRODUCTION

(75) Inventors: ERICH KLEIN, HIMBERG (AT); HEINZ RENNER, KALTENLEUTGEBEN (AT)

Correspondence Address: CORPORATE PATENT COUNSEL, U S PHILIPS CORPORATION, 580 WHITE PLAINS ROAD, TARRYTOWN, NY, 10591

(73) Assignee: U.S. PHILIPS CORPORATION

(21) Appl. No.: 09/128,835

(22) Filed: Aug. 4, 1998

(30) Foreign Application Priority Data
Aug. 5, 1997 (EP) 97890155.1

(51) Int. Cl. H05K 5/00; H04R 9/06

(52) U.S. Cl. 381/389; 381/333; 181/151

(57) ABSTRACT

In a device (8) which includes an electroacoustic transducer (7) for the acoustic reproduction of sound signals to an ear (14) of a user (2) who assumes a user position at the device (8), the transducer (7) is optimized for the acoustic reproduction of speech-signal sound waves and is equipped with additional means (25) for realizing a distinct directivity for the speech-signal sound waves emitted by said transducer (7) and, as a result of its directivity, the transducer (7) directs the speech-signal sound waves which it emits preferentially to the ear (14) of a user (2) who is in the user posture.

The invention relates to a device, in which a user can assume a user posture and which comprises a carrier for carrying at least one electroacoustic transducer, which carrier is made of an acoustically dense material and extends comparatively close to at least one ear of a user who is in the user posture, to which carrier an electroacoustic transducer is attached for the acoustic reproduction of sound signals for an ear of a user who is in the user posture, which transducer comprises sound-generation means for generating and emitting sound waves.

Such a device of the type defined in the opening paragraph is known from, for example, the document U.S. Pat. No. 4,027,112 A. The known device is a seat for a motor vehicle, which seat has a headrest for supporting the head of a user whose user posture is a sitting posture, which headrest is for the greater part formed by a supporting body provided as the carrier and consisting of an acoustically dense material, which supporting body has two recesses which are each located adjacent a supporting zone for the head and which each accommodate an electroacoustic transducer. The two electroacoustic transducers are constructed for an optimum acoustic reproduction of stereo signals, i.e. essentially music signals. Owing to their arrangement on the headrest the two electroacoustic transducers are directed with their front sides towards the head of a user who is in a sitting posture but, in order to achieve said optimum reproduction of stereo signals, both transducers radiate sound waves whose intensities are the same as far as possible over an as large as possible angular range. As a result of this, the sound waves radiated by the two transducers not only reach the ears of the user, who is in a sitting posture, and can consequently be heard by the user with a volume set and desired by the user but can also be heard by other nearby persons, for example next to or behind the user. Quite frequently, this is annoying to these nearby persons. Moreover, with respect to the known seat it is to be noted that the transducers arranged in the known seat and intended for an optimum reproduction of stereo signals are not capable of satisfactorily reproducing pure speech-signal sound waves as occur, for example, during handsfree operation of a telecommunication device.

It is an object of the invention to preclude the afore-mentioned situation in a device of the type defined in the opening paragraph in a simple and economical manner and to provide an improved device of the type defined in the opening paragraph. According to the invention, in order to achieve this object, a device of the type defined in the opening paragraph is characterized in that the transducer is constructed for an optimum acoustic reproduction of speech-signal sound waves and the transducer is equipped with additional means for realizing a distinct directivity for the speech-signal sound waves emitted by said transducer and, as a result of its directivity, the transducer directs the speech-signal sound waves which it emits preferentially to an ear of a user who is in the user posture.

By means of the measures in accordance with the invention a device is obtained in a simple, cheap and easy to realize manner, on which a user can assume a user posture—such as a sitting posture or a reclining posture—and which guarantees a satisfactory acoustic reproduction of speech and which, in addition, as a result of the radiation of speech-signal sound waves with a high intensity in a very small angular range owing to the distinct directivity provides a particularly well-aimed radiation towards an ear of a user who has assumed a user posture, which has the advantage that a highly satisfactory sound reception is achieved for a user of a device in accordance with the invention without any undesirable sound radiation of speech-signal sound waves in the vicinity of the user, so that hardly any inconvenience is caused to a person near the user. The well-aimed radiation achieved as a result of the distinct directivity further makes it possible for the user of a device in accordance with the invention to assure for a reproduction volume setting he has chosen that overhearing by a person near the user is substantially impossible in the case of speech reproduction, which is for example desirable when confidential information is communicated to the user during a telephone call made with the aid of the transducer accommodated in the product. In a transducer in accordance with the invention it has proved to be advantageous if the transducer is optimized for the reproduction of speech signals in a frequency range between approximately 500 Hz and 5 kHz.

It is to be noted that from the document EP 0 368 291 A1 a device, i.e. a seat of a motor vehicle, is known in which an electroacoustic transducer is accommodated in the area of a headrest, which transducer is adapted or constructed particularly for an acoustically correct reproduction of speech-signal sound waves. However, in said known seat the transducer accommodated in the seat, i.e. in the headrest of this seat, does not comprise additional means for realizing the distinct directivity for the speech-signal sound waves emitted by this transducer, so that this transducer radiates speech-signal sound waves with high intensity not only in a small angular range but in a comparatively large angular range, as a result of which this known device does not have the advantages of the invention provided by a device in accordance with the invention.

In a device in accordance with the invention having the characteristic features defined in the independent claim 1 it has proved to be very advantageous if, in addition, the measures defined in the dependent claim 2 are taken. Such an embodiment has proved to be particularly effective and functional in practical tests. A further advantage of such an embodiment of the invention is that the baffle used in this embodiment can be used at the same time for mechanically supporting the electroacoustic transducer.

In a device in accordance with the invention having the characteristic features defined in the dependent claim 2 the additional means for realizing a distinct directivity for the speech-signal sound waves emitted by the transducer may include, in addition to the baffle, a felt-material configuration which forms an acoustic delay element. However, in a device in accordance with the invention having the characteristic features defined in the dependent claim 2 it has proved to be very advantageous if, in addition, the measures defined in the dependent claim 3 are taken. Such a foam-material configuration has the advantage that by a suitable choice of the structure of the foam material which is used the influence of the propagation time of the speech-signal sound waves by means of the relevant foam material can be adapted very simply and effectively to different requirements and conditions. The choice of the structure of a foam material may concern, for example, the density of a foam material and/or the air permeability of a foam material.

In a device in accordance with the invention having the characteristic features defined in the dependent claim 3 it has proved to be particularly advantageous if, in addition, the measures defined in the dependent claim 4 are taken. In this way a higher effectiveness of the foam-material configuration can be achieved.

In a device in accordance with the invention having the characteristic features defined in the dependent claim 4 it has proved to be very advantageous if, in addition, the measures defined in the dependent claim 5 are taken. In this way it is achieved that the foam-material configuration is used for filling the space in the at least one opening up to the carrier of the device, which is particularly advantageous if the entire carrier, together with the electroacoustic transducer accommodated therein and the additional means, is covered or upholstered with a cover, for example a fabric or the like.

In a device in accordance with the invention having the characteristic features defined in the dependent claim 3 it has further proved to be very advantageous if, in addition, the measures defined in the dependent claim 6 are taken. Such an embodiment is advantageous for simply assembling a transducer already connected to a baffle and a foam-material configuration so as to form an intermediate device and for simply building this intermediate device into a device in accordance with the invention. It is to be noted that the measures in accordance with the dependent claim 6 can also be applied advantageously to the devices in accordance with the invention having the characteristic features defined in the dependent claims 4 and 5.

In a device in accordance with the invention having the characteristic features defined in the dependent claim 3 it has further proved to be very advantageous if, in addition, the measures defined in the dependent claim 7 are taken. This is advantageous in view of a particularly simple and low-cost construction. It is to be noted that the measures in accordance with the dependent claim 7 can also be applied advantageously to the devices in accordance with the invention having the characteristic features defined in the dependent claims 4, 5 and 6.

In a device in accordance with the invention having the characteristic features defined in the independent claim 1 it has further proved to be very advantageous if, in addition, the measures defined in the dependent claim 8 are taken. Such an embodiment is very advantageous because it is particularly simple from a constructional point of view. It is to be noted that the measures in accordance with the dependent claim 8 can also be applied advantageously to the devices in accordance with the invention having the characteristic features defined in the dependent claims 2, 3, 4, 5, 6 and 7.

In a device in accordance with the invention having the characteristic features defined in the dependent claim 8 it has proved to be very advantageous if, in addition, the measures defined in the dependent claim 9 are taken. Such an embodiment has proved to be very favorable in practical tests.

In a device in accordance with the invention having the characteristic features defined in the dependent claim 3 it has further proved to be very advantageous if, in addition, the measures defined in the dependent claim 10 are taken. Such an embodiment has also proved to be very advantageous in practical tests. It is to be noted that the measures in accordance with the dependent claim 10 can also be applied advantageously to the devices in accordance with the invention having the characteristic features defined in the dependent claims 4, 5, 6, 7, 8 and 9.

However, in a device in accordance with the invention having the characteristic features defined in the dependent claim 3 it has also proved to be very advantageous if, in addition, the measures defined in the dependent claim 11 are taken. Such an embodiment has also proved to be very advantageous in practical tests. It is to be noted that the measures in accordance with the dependent claim 11 can also be applied advantageously to the devices in accordance with the invention having the characteristic features defined in the dependent claims 4, 5, 6, 7, 8 and 9.

However, it is to be noted that a foam-material configuration can also consist of other materials than those mentioned hereinbefore.

In a device in accordance with the invention having the characteristic features defined in the independent claim 1 it has furthermore proved to be very advantageous if, in addition, the measures defined in the dependent claim 12 are taken. The measures in accordance with the invention have proved to be very advantageous in such a device. It is to be noted that the measures in accordance with the dependent claim 12 can also be applied advantageously to the devices in accordance with the invention having the characteristic features defined in the dependent claims 2 to 11. Moreover, it is to be noted that a device in accordance with the invention can be constructed not only as a seat but, for example, as a bed, sofa or couch.

In a device in accordance with the invention having the characteristic features defined in the dependent claim 12 it has also proved to be very advantageous if, in addition, the measures defined in the dependent claim 13 are taken. In the case of a device in accordance with the invention constructed as a seat for a motor vehicle the measures in accordance with the invention are found to be particularly advantageous and attractive to many users.

In a device in accordance with the invention having the characteristic features defined in the independent claim 1 it has further proved to be very advantageous if, in addition, the measures defined in the dependent claim 14 are taken. Providing for example two transducers which each have a distinct directivity has the advantage of a gain in volume and, consequently, a particularly good acoustic speech-signal reception. If required, it is also possible to connect four transducers to the carrier of which each tome two transducers emit speech-signal sound waves to one ear of a user. It is to be noted that the measures in accordance with the dependent claim 14 can also be applied advantageously to the devices in accordance with the invention having the characteristic features defined in the dependent claims 2 to 13.

The afore-mentioned aspects as well as further aspects of the invention will be apparent from the embodiments described hereinafter by way of examples and will be elucidated on the basis of these embodiments.

The invention will now be described in more detail with reference to some embodiments shown in the drawings and given by way of examples, but to which the invention is not limited.

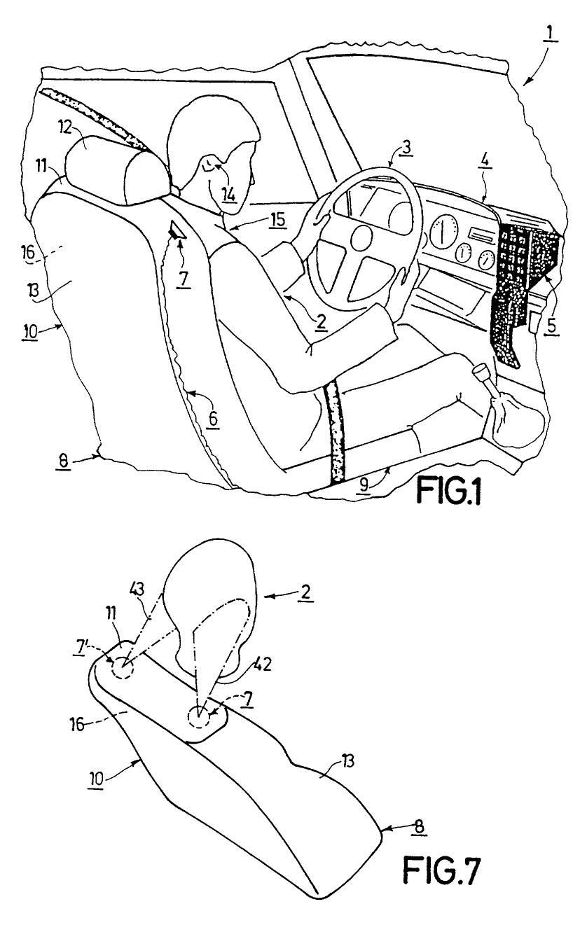

FIG. 1 shows diagrammatically a part of a motor vehicle with a driver's seat in accordance with a first embodiment of the invention, which seat has a built-in electroacoustic transducer for emitting speech-signal sound waves, which transducer is shown only diagrammatically in FIG. 1.

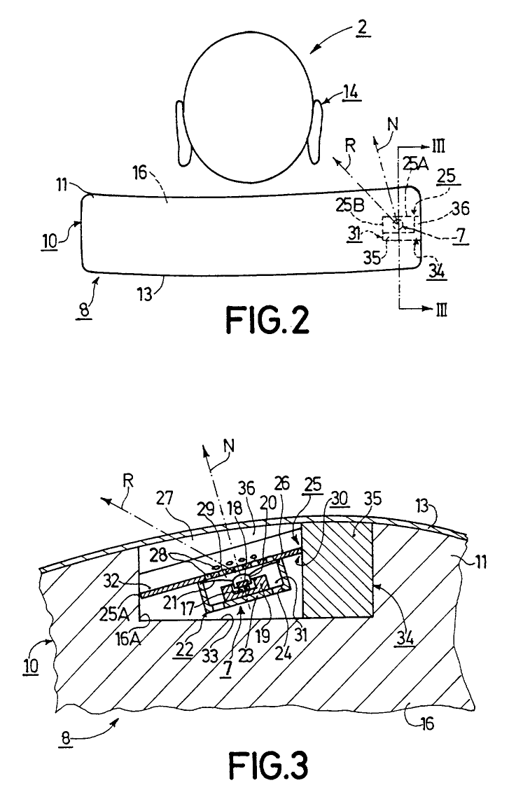

FIG. 2 shows a plan view of the upper part of the driver's seat of the motor vehicle of FIG. 1, including the built-in electroacoustic transducer, which is equipped with additional means for realizing a distinct directivity for the speech-signal sound waves emitted by this transducer, and also shows diagrammatically the head of a driver sitting on the driver's seat.

FIG. 3 shows the upper part of the driver's seat of the motor vehicle of FIG. 1, including the built-in electroacoustic transducer and the additional means for realizing a distinct directivity, in a cross-sectional view taken on the line III-III.

FIG. 4 is a sectional view taken along a plane of section substantially perpendicular to the plane of section taken on the line III-III in FIG. 2 and shows the upper part of a driver's seat in a second embodiment of the invention, including a built-in electroacoustic transducer equipped with additional means for realizing a distinct directivity for the speech-signal sound waves emitted by this transducer.

FIG. 5, in the same way as FIG. 4, shows the upper part of a driver's seat in a third embodiment of the invention, including a built-in electroacoustic transducer equipped with additional means for realizing a distinct directivity for the speech-signal sound waves emitted by this transducer.

FIG. 7, in the same way as FIGS. 4 and 5, shows the upper part of a driver's seat in a fourth embodiment of the invention, including a built-in electroacoustic transducer equipped with additional means for realizing a distinct directivity for the speech-signal sound waves emitted by this transducer.

FIG. 7 shows diagrammatically the back of a seat of a motor vehicle in a fifth embodiment of the invention, the seat having two built-in electroacoustic transducers.

FIG. 1 shows that part of a motor vehicle 1 which is relevant in the present context. In principle, only that part of the motor vehicle 1 is shown which is intended for the driver 2 of the motor vehicle 1, the driver being shown diagrammatically. This part includes a steering wheel 3 as well as a dashboard 4, which is equipped with, inter alia, a telephone set 5. The telephone set 5 is constructed for handsfree operation, in which mode of operation words spoken by the driver 2 are picked up by a microphone incorporated in the telephone set 5 and speech signals received by means of the telephone set 5 are applied to an electroacoustic transducer 7, shown diagrammatically, via an electrically conductive connection 6, which is shown only partly and diagrammatically. The electroacoustic transducer 7 is constructed as a loudspeaker.

The part of the motor vehicle 1 shown in FIG. 1 further includes a device in accordance with the invention, i.e. a seat 8 for the motor vehicle 1. The seat 8 essentially comprises a bottom part 9 and a back 10 whose upper part 11 carries a headrest 12.

A user of the seat 8, i.e. the driver 2, can assume a user posture on the seat 8, in the present case a sitting posture, as is shown in FIG. 1.

The area of the upper part 11 of the seat 8 is also shown in FIGS. 2 and 3, but without the headrest 12. As is apparent from FIG. 3, the seat 8 may be upholstered with a cover 13 of a fabric or a similar material. To support the body of the driver 2, i.e. also to support at least a part of the body which is situated comparatively close to an ear—such as the shoulder area 15 near the right ear 14 of driver 2—of the driver 2 in the user posture, the seat 8 comprises a supporting body 16 of an acoustically dense material, which supporting body serves as a carrier for an electroacoustic transducer and extends comparatively close to the ear 14 of the driver 2. The afore-mentioned electroacoustic transducer 7 is connected to carrier formed by the supporting body 17 for acoustically reproducing sound signals for the ear 14 of the driver 2 in the user posture, the transducer 7 being built into the supporting body 16, for which purpose the supporting body 16 has a recess 16A which accommodates the transducer 7.

The electroacoustic transducer 7 is shown diagrammatically but in greater detail in FIG. 3. The transducer 7 comprises a magnet 17 which adjoins a disc-shaped cover plate 18 at one side and a pot-shaped yoke 19 at the other side. Between the free end face of the pot-shaped yoke 19 and the cover plate 18 an annular air gap is formed, into which a moving coil 20 projects, which is mechanically attached to a diaphragm 21. The diaphragm 21 forms sound-generation means for generating and emitting sound waves, which means are disposed in the area of the transducer 7 which is remote from the supporting body 16. The diaphragm 21 is fixedly attached to a substantially pot-shaped housing 22 of the transducer 7 in the area of a free end face of the housing 22, for example by means of an adhesive joint. The housing 22 also accommodates the pot-shaped yoke 19, the magnet 17 and the cover plate 18, these three parts 17, 18 and 19, which form the magnet system of the transducer 7, each being connected to one another and to the housing, respectively, by means of an adhesive joint. It is to be noted that in the area of its bottom wall 23 the housing 22 has a plurality of passages 24, which means that the housing is acoustically open towards the rear.

Advantageously, the transducer 7 in the seat 8 shown in FIGS. 1, 2 and 3 is constructed so as to achieve an optimum acoustic reproduction of speech-signal sound waves. In the transducer 7 this is achieved in a manner known per se by a suitable construction of its magnet system 17, 18 and 19, its moving coil 20, its diaphragm 21 and its housing 22. This construction of the transducer 7 guarantees a correct sound reproduction in a frequency range from approximately 500 Hz to approximately 5 kHz, which is particularly advantageous for an optimum acoustic reproduction of speech-signal sound waves.

The transducer 7 in the seat 8 further comprises additional means 25 for realizing a distinct directivity for the speech-signal sound waves which it emits and, as a result of its directivity, the transducer 7 directs the speech-signal sound waves which it emits preferentially to the right ear 14 of the driver 2 in the sitting posture.

In the present case the additional means 25 comprise a baffle 26 interposed between the transducer 7 and the acoustic free space. The acoustic free space bears the reference numeral 27 in FIG. 3. It is emphasized that the acoustic free space 27 is situated not only inside the recess 16A in the supporting body 16 but also outside the cover 13 for the supporting body 16. The baffle 26 is wholly accommodated in the recess 16A and has its long side wall 25A and its short side wall 25B connected to the respective side walls of the recess 16A, preferably during the foaming process; however, such a connection can also be made by means of a kind of press-fit or by means of an adhesive joint. The transducer 7 is connected to the baffle 26 in an acoustically imperforate manner. In the present case this is achieved in that the free end face of the pot-shaped housing 22 of the transducer 7 is connected to the baffle 26 by means of an adhesive.

The baffle 26 has a plurality of sound ports 28 which connect the front volume 29 of the transducer 7, which is situated in front of the diaphragm, to the acoustic free space 27. As is apparent from FIG. 3 and also from FIG. 2, the baffle 26 does not cover the whole cross-sectional area of the recess 16A in the supporting body 16 but the baffle 26 has a substantially L-shaped opening 30, which connects the back volume 31 of the transducer 7, which volume is situated behind the diaphragm 21, to the acoustic free space 27, which connection in the present case is made via the passages 24 in the bottom wall 23 of the pot-shaped housing 22 and via a part of the recess 16A in the supporting body 16. By means of the baffle 26 the speech-signal sound waves emitted into the free space 27 via the back volume 31, the passages 24 in the bottom wall 23 of the pot-shaped housing 22, a part of the recess 16A in the supporting body 16 and the opening 30 can be delayed to different extents in different directions. Thus, it is achieved in a manner known per se that speech-signal sound waves emitted by the diaphragm 21 via the back volume 31 and the opening 30 produce a comparatively strong attenuation of speech-signal sound waves emitted towards the opening 30 via the front volume 29, while the speech-signal sound waves emitted towards the imperforate area 32 of the baffle 26 via the front volume 29 cannot be attenuated by speech-signal sound waves propagating via the back volume 31 and the passages 24 because said area 32 is imperforate, as a result of which speech-signal sound waves emitted towards the imperforate area 32 of the baffle 26 via the front volume 29 are transmitted substantially without attenuation. Thus, a distinct directivity for the speech-signal sound waves emitted by the transducer 7 is obtained by means of the baffle 26. As a result of this distinct directivity the transducer 7 preferentially emits speech-signal sound waves to the right ear 14 of the driver 2 in the direction indicated by means of a dash-dot arrow R.

As regards the baffle 26 it is to be noted that the baffle 26 is arranged in an inclined position with respect to the bottom wall 33 of the recess 16A, the baffle 26 being inclined with respect to the bottom wall 33 in directions parallel to the plane of drawing in FIG. 3 as well as perpendicular to the plane of drawing, as a result of which a normal to the plane indicated by a dash-dot arrow N in FIGS. 2 and 3 is directed as shown in FIGS. 2 and 3.

In the seat 8 the additional means 25 for realizing a distinct directivity for the speech-signal sound waves emitted by the transducer 7 include, in addition to the baffle 26, a foam-material configuration 34 which forms an acoustic delay element. In the present case, this foam-material configuration 34 is essentially L-shaped and comprises a portion 35, which in FIG. 3 extends perpendicularly to the plane of section indicated by the line III-III in FIG. 2, and a portion 36, which extends substantially perpendicularly to the portion 35 and which projects laterally from the portion 36. In its area which is remote from the bottom wall 33 of the recess 16A the two portions 35 and 36 are rounded in accordance with the curved shape of the supporting body 16 and the curved shape of the cover 13 around the supporting body 16.

The foam-material configuration 34 is arranged in the sound path of the speech-signal sound waves emitted to the acoustic free space 27 via the back volume 31, the passages 24 and the opening 30 and partly encloses the transducer 7 in conformity with its L shape. As is apparent from FIG. 3, the foam-material configuration 34 in the present case fills the opening 30 up to the supporting body 16. Advantageously, the foam-material configuration 34 consists of a single part of a forma material. In the present case the foam-material configuration consists of open-pore and if necessary densified polyurethane; however, it may alternatively consist of any other foam material. By means of the foam-material configuration 34 the speech-signal sound waves emitted into the acoustic free space 27 via the back volume 31, the passages 24 and the opening 30 can be influenced as regards their propagation time, which in addition enables the distinct directivity for the speech-signal sound waves emitted by the transducer 7 to be influenced in an advantageous manner.

As a result of the provision of the baffle 26 and the additional provision of the foam-material configuration 34 in the seat 8 it is achieved in a very simple manner that the transducer exhibits a distinct directivity for the speech-signal sound waves which it emits and that owing to its directivity the transducer emits the speech-signal sound waves preferentially to the right ear 14 of the driver 2, who is in the sitting posture.

FIG. 4 shows a seat 8 in accordance with a second embodiment of the invention. The supporting body 16 forming the carrier in this seat 8 also has a recess 16A which accommodates an electroacoustic transducer 7 comprising a magnet system 17, 18 and 19, a moving coil 20, a diaphragm 21 and a pot-shaped housing 22. The transducer 7 which is arranged in the seat 8 shown in FIG. 4 and which is constructed to provide a correct acoustic reproduction of speech-signal sound waves also has additional means 25 for realizing a distinct directivity for the speech-signal sound waves emitted by the transducer 7. Here, these additional means 25 also comprise a baffle 26 and a foam-material configuration 34. In the present case, the baffle 26 has, in addition to the sound ports 28, some further passages forming openings 30, of which only a single opening 30 is visible in FIG. 4. In the present case, the foam-material configuration 34 extends up to the openings 30 in the baffle 26. The foam-material configuration 34 is now pot-shaped and is accommodated in a correspondingly pot-shaped recess 16A in the supporting body 16. The transducer 7 is mounted in the pot-shaped foam-material configuration 34. In the present case, the foam-material configuration 34 consists of open-pore and/or densified polyurethane but may alternatively consist of other foam materials.

FIG. 5 shows a seat 8 in accordance with a third embodiment of the invention. The seat 8 in the present embodiment bears comparatively much resemblance to the seat 8 but an essential difference resides in the structure of the foam-material configurations 34 in the seats 8 of FIGS. 4 and 5.

Whereas the foam-material configuration 34 in the seat 8 of FIG. 4 comprises a single foam-material part the foam-material configuration 34 in the seat 8 of FIG. 5 comprises two foam-material parts 37 and 38. One foam-material part 37 is disc-shaped, is disposed on the bottom wall 33 of the recess 16A and supports the bottom wall 23 of the pot-shaped housing. The other foam-material part 38 has a semi-annular shape in such a manner that it borders on all the openings 30 in the baffle 26.

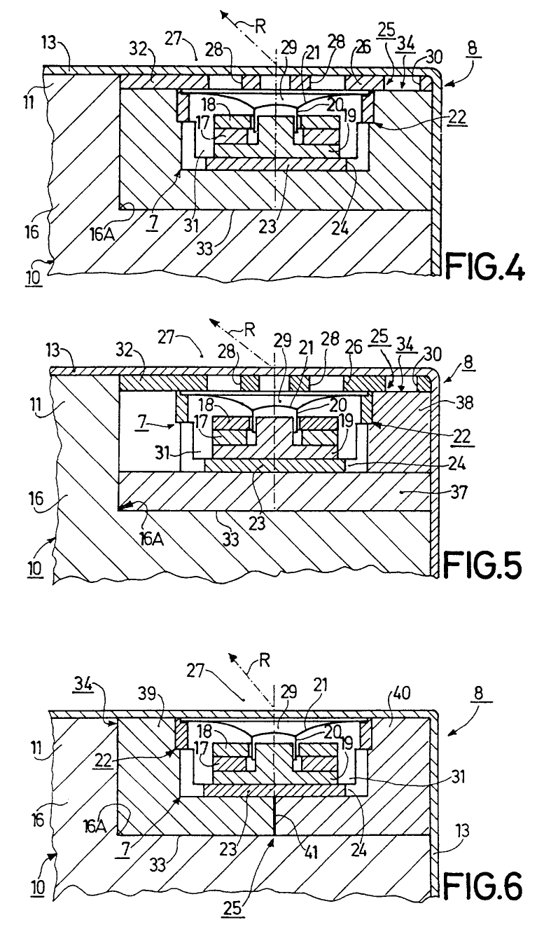

FIG. 6 shows a seat 8 in accordance with a fourth embodiment of the invention, which differs from the two seats 8 of FIGS. 4 and 5 in that in the present case the additional means 25 of the transducer 7, which serve for realizing a distinct directivity for the speech-signal sound waves emitted by the transducer 7, do not comprise a baffle but in a particularly simple manner are formed by a foam-material configuration 34 comprising two foam-material parts having different foam material structures. The two foam-material parts 39 and 40 each have the shape of a half pot, in such a manner that in conformity with their shape they enclose the transducer 7 in the area of its back volume 31 both circumferentially and at the bottom side. The two foam-material parts 39 and 40 adjoin one another directly at the location of a separating zone 41. Furthermore, the free end face of the semi-annular portion corresponding to the half-pot shape of each of the two foam-material parts 39 and 40 directly adjoins the acoustic free space 27, where said end faces are shrouded by the cover 13. In the seat 8 of FIG. 6 the one foam-material part 39 consists of an acoustically dense foam material and the other foam-material part 40 consists of an acoustically permeable foam material. This choice of the foam material for the two foam-material parts 39 and 40 results in a distinct directivity for the speech-signal sound waves emitted by the transducer 7, so that the transducer 7 preferentially emits speech-signal sound waves to an ear of a user of the seat 8 in the direction indicated by means of a dash-dot arrow R.

FIG. 7 diagrammatically shows the back 10 of a seat 8 in accordance with a fifth embodiment of the invention. In this seat 8 the supporting body 16 forming the carrier carries a pair of electroacoustic transducers 7 and 7′ for the optimum reproduction of speech-signal sound waves, each of these two transducers 7 and 7′ being provided, in a manner not shown, with additional means for realizing a distinct directivity for the speech-signal sound waves which they emit and each of the two transducers 7 and 7′, as a result of the directivity, preferentially emitting speech-signal sound waves to one of the two ears of a user of the seat 8, who is in a sitting posture, as is indicated diagrammatically by means of two dash-dotted sound-emission cones 42 and 43 in FIG. 7.

The invention is not limited to the embodiments described hereinbefore by way of examples. For example, a foam-material configuration may comprise more than two foam-material parts. In alternatives to the embodiments shown in FIGS. 4 and 5 a baffle may be provided, which may be inclined with respect to the bottom wall of the recess in at least one direction -preferably also in two directions. Instead of in the upper part of the back of a seat, an electroacoustic transducer together with its additional means for realizing a distinct directivity can be mounted in a headrest attached to the back of the seat. Furthermore, it is to be noted that an electroacoustic transducer together with its additional means for realizing a distinct directivity need not necessarily be built into a seat but can also be accommodated in a unit arranged on the outside of a seat, which unit may also be constructed as a an add-on unit, which has the advantage that the advantages of the invention can also be obtained for existing seats or similar devices. A device in accordance with the invention need not necessarily be constructed as a seat but can also be constructed as a couch, a patient chair or a patient couch. Moreover, the measures in accordance with the invention can also be applied to aircraft or train seats. Finally, a device in accordance with the invention need not necessarily be constructed as a seat, patient chair, couch or the like but can also be constituted by the roof or the roof area of a motor vehicle or by an overhead service unit for passengers in an aircraft.

1. A device,
in which a user can assume a user posture and
which comprises a carrier for carrying at least one electroacoustic transducer, which carrier is made of an acoustically dense material and extends comparatively close to at least one ear of a user who is in the user posture, to which carrier an electroacoustic transducer is attached for the acoustic reproduction of sound signals for an ear of a user who is in the user posture, which transducer comprises sound-generation means for generating and emitting sound waves,
characterized in that
the transducer is constructed for an optimum acoustic reproduction of speech-signal sound waves and
the transducer is equipped with additional means for realizing a distinct directivity for the speech-signal sound waves emitted by said transducer and,
as a result of its directivity, the transducer directs the speech-signal sound waves which it emits preferentially to an ear of a user who is in the user posture.

2. A device as claimed in claim 1, characterized in that the additional means comprise a baffle interposed between the transducer and the acoustic free space, to which baffle the transducer is connected in an acoustically imperforate manner and which baffle has at least one sound port—which connects the front volume situated in front of the sound generation means to the acoustic free space—and at least one opening—which connects the back volume situated behind the sound generation means to the acoustic free space—and by means of which baffle the speech-signal sound waves emitted into the free space via the back volume 31 and the at least one opening can be delayed, with respect to the speech-signal sound waves emitted via the front volume and the at least one sound port, to different extents in different directions.

3. A device as claimed in claim 2, characterized in that, in addition to the baffle, the additional means comprise a foam-material configuration which constitutes an acoustic delay element and the foam-material configuration is arranged in the area of the sound path of the speech-signal sound waves emitted into the acoustic free space via the back volume and the at least one opening and partly encloses the transducer.

4. A device as claimed in claim 3, characterized in that the foam-material configuration extends at least up to the at least one opening in the baffle.

5. A device as claimed in claim 4, characterized in that the foam-material configuration fills the space in the at least one opening up to the carrier.

6. A device as claimed in claim 3, characterized in that the foam-material configuration is pot-shaped and is accommodated in a correspondingly pot-shaped recess in the carrier, and the transducer is mounted in the pot-shaped foam-material configuration.

7. A device as claimed in claim 4, characterized in that the foam-material configuration consists of a single foam-material part.

8. A device as claimed in claim 1, characterized in that the additional means are constituted by a foam-material configuration which comprises at least two foam-material parts having different foam-material structures, and the foam-material parts at least circumferentially enclose the transducer in the area of its back volume and directly adjoin one another pairwise and each directly adjoin the acoustic free space.

9. A device as claimed in claim 8, characterized in that one of the foam-material parts consists of an acoustically dense foam material.

10. A device as claimed in claim 3, characterized in that the foam-material configuration consists of open-pore and if necessary densified polyurethane.

11. A device as claimed in claim 3, characterized in that the foam-material configuration consists of open-pore and if necessary densified polyethylene.

12. A device as claimed in claim 1, characterized in that the device is constructed as a seat.

13. A device as claimed in claim 1, characterized in that the device is constructed as a seat for a motor vehicle.

14. A device as claimed in claim 1, characterized in that at least one pair of transducers is attached to the carrier, and each of these transducers is equipped with additional means for realizing a distinct directivity for the speech-signal sound waves emitted by said transducer and,
as a result of their directivities, one transducer of each pair of transducers directs the speech-signal sound waves which it emits preferentially to one of the two ears of a user who is in the user posture and the other transducer directs the speech-signal sound waves which it emits preferentially to the other one of the two ears of this user.
